(19) United States
(12) Patent Application Publication
(10) Pub. No.: US 2011/0115469 A1
(43) Pub. Date: May 19, 2011

(54) OPTICAL FIBER ELECTRIC CURRENT SENSOR, ELECTRIC CURRENT MEASUREMENT METHOD, AND FAULT ZONE DETECTION APPARATUS

(75) Inventors: Reishi Kondo, Ichikawa-shi (JP); Kiyoshi Kurosawa, Tokyo (JP); Shinsuke Nasukawa, Tokyo (JP); Taro Kuramochi, Tokyo (JP); Toshiharu Yamada, Oyama-shi (JP); Eiji Itakura, Oyama-shi (JP)

(73) Assignees: THE TOKYO ELECTRIC POWER COMPANY, INCORPORATED, Chiyoda-ku, Tokyo (JP); TAKAOKA ELECTRIC MFG. CO., LTD., Chuo-ku, Tokyo (JP)

(21) Appl. No.: 13/054,213

(22) PCT Filed: Jul. 15, 2009
(86) PCT No.: PCT/JP2009/062834

§ 371 Date: Jan. 14, 2011

(30) Foreign Application Priority Data
Jul. 18, 2008 (JP) 2008-187867

(51) Int. Cl. G01R 31/00

(52) U.S. Cl. 324/96; 359/283

(57) ABSTRACT

An optical fiber electric current sensor includes a polarization-splitter (13) that splits light outputted from a sensor fiber (11) into two polarization planes of which polarization directions are perpendicular to each other, a depolarizer (17) that depolarizes each of the polarization components from the polarization-splitter (13), light receiving element that converts the two lights that were depolarized by the depolarizer (17) to a first signal (S1) and a second signal (S2) respectively, and a signal processing unit (15) that, based on the first signal (S1) and the second signal (S2), determines the magnitude of a Faraday rotation applied to the linearly-polarized light, and thereby calculates a value of the current to be measured.

### TECHNICAL FIELD

The present invention relates to a technology for measuring an electric current using Faraday Effect whereby a polarization plane of light propagating through an optical fiber is rotated by a magnetic field.

Priority is claimed on Japanese Patent Application No. 2008-187867, filed Jul. 18, 2008, the contents of which are incorporated herein by reference.

### BACKGROUND ART

Recently, an optical fiber electric current sensor which uses an optical fiber as a sensor is attracting attention as an electric current measurement apparatus that performs monitoring and the like of an electric power system (e.g. refer to Patent Document 1).

This optical fiber electric current sensor uses the Faraday effect, whereby the polarization plane of light propagating through a magnetic medium is rotated in proportion to the magnitude of the magnetic field in a propagation direction thereof, to measure electric current. The optical fiber is also a sort of magnetic medium. If the linearly-polarized light is incident to the optical fiber which is used as a sensor, and the optical fiber is placed near to a conductor wherein a current to be measured is flowing (i.e. a magnetic field source), the rotation (Faraday rotation) to the plane of polarization of the linearly-polarized light in the optical fiber due to the Faraday effect. At this moment, since magnetic fields are generated in proportion to the current, the rotation angle (Faraday rotation angle) of the polarization plane caused by the Faraday effect is proportional to the magnitude of the measurement current. In this regard, the magnitude of the current can be obtained by measuring the Faraday rotation angle. This is a principle of the optical fiber electric current sensor.

### PRIOR ART DOCUMENT

### Patent Document

[Patent Document 1] Japanese Patent Application, Publication No. 2006-46978

### SUMMARY OF INVENTION

### Problems to be Solved by the Invention

When, for example, a single-mode fiber is used as a transmission path for transmitting light, which is outputted from a sensor after Faraday rotation was appended to it, to a light receiving element, displacement of the transmission path due to vibrations and the like leads to fluctuation of the polarization state of light propagating along the transmission path. On the other hand, the photoelectric conversion efficiency of a light receiving element (a photodiode) is not completely polarized light-independent, and has a slight polarized-light dependency. When there is fluctuation in the polarization state of light output from the sensor as it propagates along the transmission path, the photoelectric conversion efficiency of the light receiving element varies in accordance with the polarization state. As a result, the optical intensity of the received light also fluctuates, leading to an erroneous measurement of the Faraday rotation angle and a reduction in the electric current measurement precision.

While a polarization-holding fiber can conceivably be used as the transmission path instead of a single-mode fiber, a polarization-holding fiber is expensive in comparison with a single-mode fiber, and is therefore not cost-effective.

Also, when using an optical fiber electric current sensor such as that described above to detect current abnormalities on a distant transmission line, a long-distance transmission path is required to transmit light to and from a sensor installed at a distant abnormality detection point. Preexisting commercial optical fiber transmission paths that can be used for this purpose are made from single-mode fibers, and cannot easily be replaced with long-distance optical transmission paths made from expensive polarization-holding fibers.

It is an object of the present invention to provide an optical current sensor, an electric current measurement method, and a fault zone detection apparatus that can detect current highly precisely, without being affected by fluctuation in the polarization state possibly generated as light output from a sensor propagates along a transmission path.

### Means for Solving the Problem

According to a first aspect of the present invention, there is provided an optical fiber electric current sensor including a sensor fiber that encloses a conductor and which linearly-polarized light is incident to, a polarization-splitter that splits light outputted from the sensor fiber into two polarization planes of which polarization directions are perpendicular to each other, a depolarizer that depolarizes each of the polarization components from the polarization-splitter, a photoelectric conversion device that converts the two lights that were depolarized by the depolarizer to a first signal and a second signal with a photoelectric conversion respectively, and a signal processing device that, based on the first signal and the second signal, determines the magnitude of a Faraday rotation applied to the linearly-polarized light, and thereby calculates a value of the current to be measured.

In the optical fiber electric current sensor according the above-mentioned aspect, a transmission path that transmits the light outputted from the polarization-splitter to the photoelectric conversion device may be configured from a single-mode optical fiber.

In the optical fiber electric current sensor according the above-mentioned aspect, the depolarizer is provided at an end of the single-mode optical fiber on the polarization-splitter side.

In the optical fiber electric current sensor according the above-mentioned aspect, the depolarizer is provided at an end of the single-mode optical fiber on the photoelectric conversion device side.

According to another aspect of the present invention, there is provided an electric current measurement method including splitting light outputted from a sensor fiber, which encloses a conductor and which linearly-polarized light is incident to, into two polarization planes of which polarization directions are perpendicular to each other, depolarizing each of the split polarization components, converting the two depolarized lights by photoelectric conversion to a first signal and a second signal respectively, and determining, based on the first signal and the second signal, the magnitude of a Faraday rotation applied to the linearly-polarized light, and thereby calculating a value of the current to be measured.

According to another aspect of the present invention, there is provided a fault zone detection apparatus including the optical fiber electric current sensor, the apparatus using the optical fiber electric current sensor to detect a fault zone in an electric transmission cable that includes an imaginary cable and an underground cable.

### Advantage of the Invention

According to aspects of the present invention, since light outputted from a sensor fiber and divided into two polarization components is depolarized by depolarizers before being subjected to photoelectric conversion, even if the polarization state fluctuates midway on the transmission path, the light intensities of the two polarizers can be accurately measured without being affected by the fluctuation, whereby the current can be measured very precisely.

### BRIEF DESCRIPTION OF THE DRAWINGS

FIG. 1 shows a configuration of an optical fiber electric current sensor according to a first embodiment.

FIG. 2 shows a configuration of an optical fiber electric current sensor according to a second embodiment.

FIG. 3 shows a configuration of a fault zone detection apparatus that uses the optical fiber electric current sensor of FIG. 2.

### DESCRIPTION OF THE EMBODIMENTS

Embodiments of the present invention will be explained while referring to the drawings.

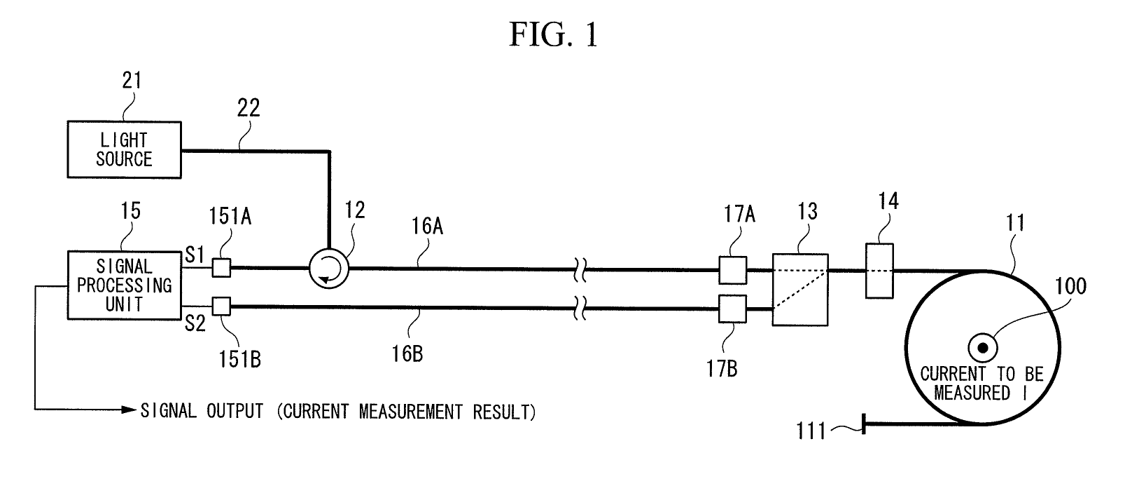

FIG. 1 is a configuration diagram of an optical fiber electric current sensor according to a first embodiment of the present invention.

In FIG. 1, the optical fiber electric current sensor includes a sensor fiber 11, an optical circulator 12, a polarization-splitter 13, a Faraday rotor 14, a signal processing unit 15, optical fibers for transmission 16A and 16B, depolarizers (depolarizing device and depolarizer) 17A and 17B, and light receiving elements (photoelectric conversion devices) 151A and 151B.

The sensor fiber 11 is arranged such that it goes around (encloses) the periphery of a conductor 100 such as a transmission wire, in which a current to be measured I flows. A lead-glass fiber, which is an optical fiber with a high Verdet constant that determines the magnitude of the Faraday effect, can appropriately be used as the sensor fiber 11. The Faraday rotor 14 is attached to one end of the sensor fiber 11, and a reflecting part (mirror) 111 is formed by depositing a metal thin film or the like at the other end. The Faraday rotor 14 and the polarization-splitter 13 are interconnected with the optical fiber, and so are two emission ends of the polarized light in the polarization-splitter 13 and the depolarizers 17A and 17B respectively. Another end portion of the depolarizer 17A is connected by an optical fiber for transmission 16A via the optical circulator 12 to the light receiving element 151A, and another end portion of the depolarizer 17B is connected by an optical fiber for transmission 16B to the light receiving element 151B. The optical circulator 12 is arranged such that light supplied from a light source 21 through an optical transmission fiber 22 is transmitted to the sensor fiber 11 side, and light from the sensor fiber 11 side that propagates in the optical fiber for transmission 16A is transmitted to the light receiving element 151A side.

In the optical fiber electric current sensor configured in this manner, light generated from the light source 21 passes through the optical transmission fiber 22, the optical circulator 12, the optical fiber for transmission 16A, and the depolarizer 17A in that order, and is incident to the polarization-splitter 13. This light is converted into linearly-polarized light of which vibration directions of electric fields are aligned in a single direction (a principal axis direction of the polarization-splitter 13) by the polarization-splitter 13, and then input to the Faraday rotor 14. The Faraday rotor 14 includes a permanent magnet and a ferromagnetic crystal, namely a ferromagnetic garnet, which has ferromagnetic crystals that are magnetically saturated by the permanent magnet, and applies a Faraday rotation of 22.5° in a single trip to the light passing through the ferromagnetic garnet. The linearly-polarized light leaving the Faraday rotor 14 is inputted to the sensor fiber 11. In a revolving portion of the sensor fiber 11, the linearly-polarized light is subjected to a Faraday rotation due to the magnetic field generated around the current to be measured I flowing through the conductor 100, and its polarization plane thereof is rotated depending on the Faraday rotation angle proportional to the magnitude of the magnetic field.

Further, the light propagating through the sensor fiber 11B is reflected at the reflecting part 111 travels through the revolving portion once again and is subjected to Faraday rotation, and enters the Faraday rotor 14. A Faraday rotation of approximately 22.5° is further applied when the light passes through the Faraday rotor 14 once again. As a result, the Faraday rotor 14 applies a total Faraday rotation of 45° in a round trip to the light propagating through the sensor fiber 11. In other words, this optical fiber electric current sensor sets an optical bias of 45°. The light passing through the Faraday rotor 14 is guided once again into the polarization splitter 13, and split into two polarization components of which polarization directions are perpendicular to each other (i.e., the principal axis direction of the polarization splitter 13 and the direction perpendicular thereto). First light split by the polarization splitter 13 is received by the light receiving element 151A via the depolarizer 17A, the optical fiber for transmission 16A, and the optical circulator 12 in that order, and converted into an electric signal S1. Meanwhile, second split light is received by the light receiving element 151B via the depolarizer 17B and the optical fiber for transmission 16B, and converted into an electric signal S2 proportional to its light intensity. Since the amount of light received at the light receiving elements 151A and 151B changes in response to the Faraday rotation angle applied to the linearly-polarized light propagating through the revolving portion of the sensor fiber 11, when the electric signals S1 and S2 reflecting this change are processed in the signal processing unit 15, it is possible to determine the Faraday rotation angle that was applied. The current to be measured I can then be measured from the Faraday rotation angle.

The depolarizers 17A and 17B depolarize the polarization state of the incident light and emit, and include, for example, fiber-type depolarizers (Takanori Okoshi, ‘Optical fiber sensor’, Ohmsha Ltd., page 41). The polarized lights emitted from the polarization-splitter 13 pass through the depolarizers 17A and 17B, whereby they are converted to depolarized lights containing all the polarization states in equal ratios, and are then emitted to the optical fibers for transmission 16A and 16B sides.

Therefore, even if the optical fibers for transmission 16A and 16B are ones where the polarization state of light propagating through them changes due to displacement in the arrangement of the fibers due to vibrations and the like, as in, for example, single-mode fibers, the depolarized lights emitted from the depolarizers 17A and 17B are received in the same depolarized states at the light receiving elements 151A and 151B, irrespective of whether there were vibrations and the like in the optical fibers for transmission 16A and 16B. Therefore, even if the photoelectric conversion efficiencies of the light receiving elements 151A and 151B are polarization-dependent, each of the light receiving elements 151A and 151B can subject the light it receives to photoelectric conversion with a photoelectric conversion efficiency that is always equal, without being affected by vibrations and the like arising in the optical fibers for transmission 16A and 16B (external turbulence capable of changing the polarization state of the light propagating through the fiber). This makes it possible to obtain electric signals S1 and S2 with stable output values from the light receiving elements 151A and 151B and then to determine highly precisely the current to be measured I.

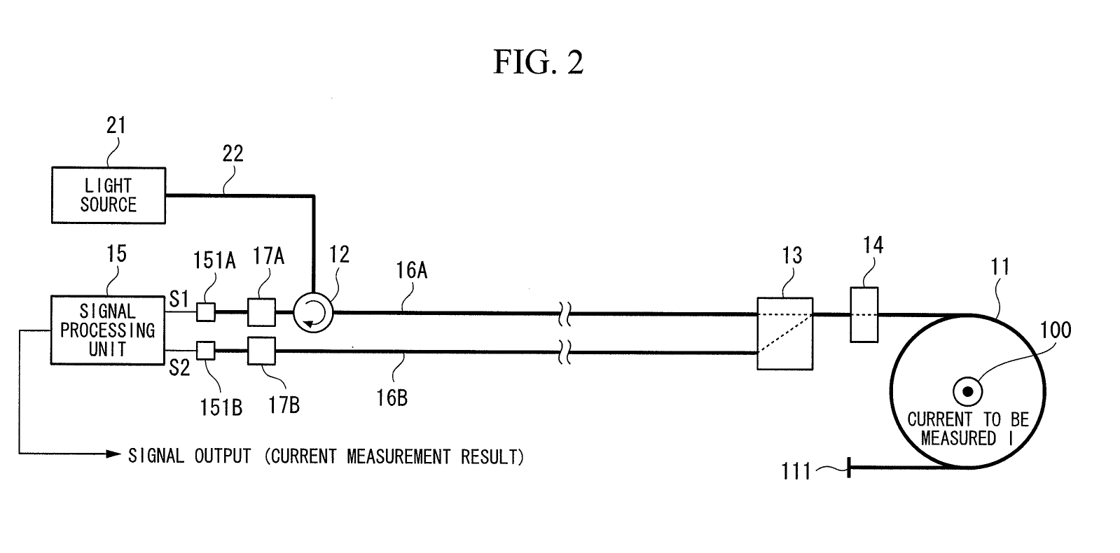

FIG. 2 shows the configuration of an optical fiber electric current sensor according to a second embodiment of the present invention.

The optical fiber electric current sensor according to the second embodiment differs from the first embodiment only in that the depolarizers 17A and 17B are arranged immediately in front of the light receiving elements 151A and 151B. Like in the first embodiment, in this configuration, depolarized lights emitted from the depolarizers 17A and 17B are received at the light receiving elements 151A and 151B. Therefore, even if there is polarization-dependent in the light receiving elements 151A and 151B, the lights can be subjected to photoelectric conversion with a photoelectric conversion efficiency that is always equal, whereby the current to be measured I can be determined with high precision.

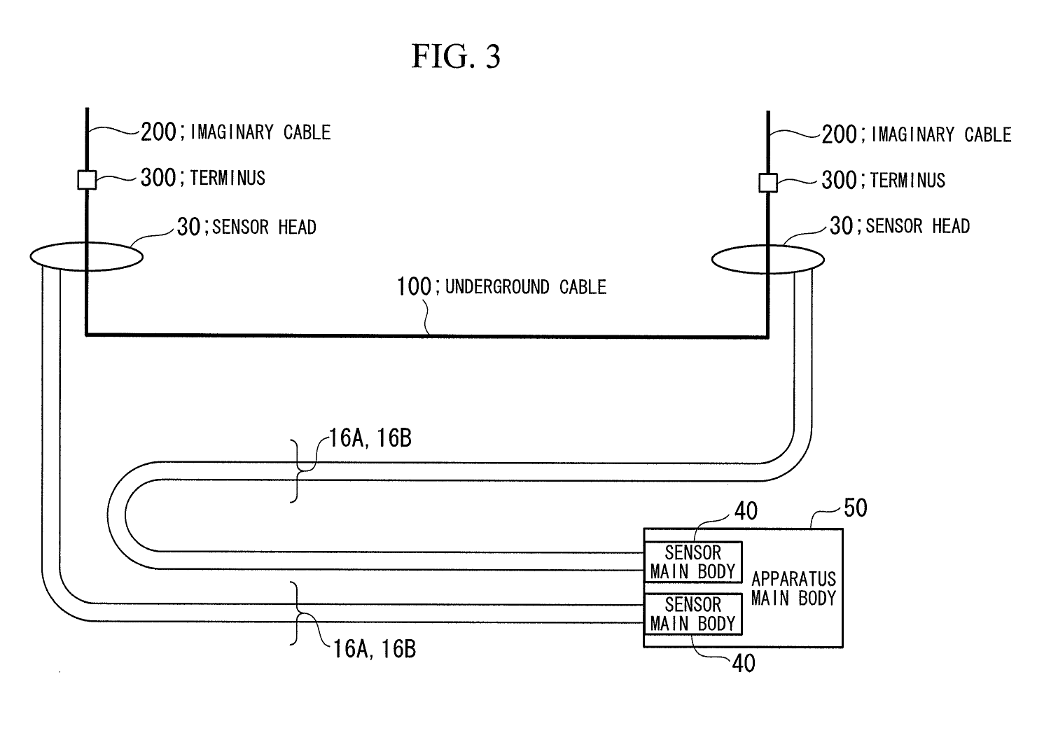

FIG. 3 shows the configuration of a fault zone detection apparatus for detecting a fault zone of an electric transmission cable, the optical fiber electric current sensor of FIG. 2 being used in this configuration.

In FIG. 3, the electric transmission cable that is the detection target of the fault zone includes an underground cable 100 (corresponding to the conductor 100 in FIG. 1) and an imaginary cable 200 connected to the underground cable 100 at a terminus 300 of the underground cable 100.

The fault zone detection apparatus is configured from two sensor heads 30, two sensor main bodies 40 provided in correspondence with the sensor heads 30, an apparatus main body 50 that accommodates the sensor main bodies 40, and optical fibers for transmission 16A and 16B. The optical fibers for transmission 16A and 16B are commercial optical fibers that are already installed, and single-mode fibers.

Each sensor head 30 includes a sensor fiber 11, a polarization-splitter 13, and a Faraday rotor 14. The two sensor heads 30 are respectively arranged near two terminuses 300 at both ends of the underground cable 100.

Each sensor main body 40 includes an optical circulator 12, a signal processing unit 15, depolarizers 17A and 17B, and light receiving elements 151A and 151B.

The main body 50 includes a light source 21 and such like.

Thus the fault zone detection apparatus includes two optical fiber electric current sensors, and each of these optical fiber electric current sensors measures the value of the current flowing along the underground cable 100. Based on a measurement result of the difference in the values of the current flowing along the underground cable 100, the fault zone detection apparatus determines whether a fault (a grounding fault caused by such as dielectric breakdown of the cable) has occurred on the underground cable 100, or whether a fault has occurred on the imaginary cable 200. For example, when a fault occurs on the underground cable 100, a difference arises between the current values measured by the two optical fiber electric current sensors, making it possible to determine that the fault is on the underground cable 100.

In the fault zone detection apparatus, while the transmission paths between the sensor heads 30 and the sensor main bodies 40 are configured from single-mode fibers, since the optical fiber electric current sensors include the depolarizers 17A and 17B, even if there is polarization-dependent in the light receiving elements 151A and 151B, the optical fiber electric current sensors can measure the current value of the underground cable 100 with high precision, enabling the fault zone to be determined accurately.

While embodiments of the invention have been described in detail with reference to the drawings, the specific configuration is not limited to the foregoing description, and various design modifications can be made without deviating from the main points of the invention.

### DESCRIPTION OF THE REFERENCE SYMBOLS

11 . . . SENSOR FIBER
12 . . . OPTICAL CIRCULATOR
13 . . . POLARIZATION SPLITTER
14 . . . FARADAY ROTOR
15 . . . SIGNAL PROCESSING UNIT
16 . . . OPTICAL FIBERS FOR TRANSMISSION
17 . . . DEPOLARIZERS
21 . . . LIGHT SOURCE
22 . . . OPTICAL TRANSMISSION FIBER
100 . . . CONDUCTOR
151 . . . LIGHT RECEIVING ELEMENTS

1. An optical fiber electric current sensor comprising:
a sensor fiber that encloses a conductor, to which linearly-polarized light is incident;
a polarization-splitter that splits light outputted from the sensor fiber into two perpendicular polarization components;
a depolarizer that depolarizes each of the polarization components from the polarization-splitter;
a photoelectric conversion device that converts the two depolarized polarization components to a first signal and a second signal respectively; and
a signal processing device that, based on the first signal and the second signal, determines the magnitude of a Faraday rotation applied to the linearly-polarized light, and thereby calculates a value of the current to be measured.

2. The optical fiber electric current sensor according to claim 1, wherein a transmission path that transmits the light outputted from the polarization-splitter to the photoelectric conversion device comprises a single-mode optical fiber.

3. The optical fiber electric current sensor according to claim 2, wherein the depolarizer is provided at an end of the single-mode optical fiber on the polarization-splitter side.

4. The optical fiber electric current sensor according to claim 2, wherein the depolarizer is provided at an end of the single-mode optical fiber on the photoelectric conversion device side.

5. An electric current measurement method comprising:
splitting light outputted from a sensor fiber enclosing a conductor to which linearly-polarized light is incident, into two polarization components which are perpendicular to each other;
depolarizing each of the split polarization components;
converting the two depolarized lights by photoelectric conversion to a first signal and a second signal respectively; and
determining, based on the first signal and second signal, the magnitude of a Faraday rotation applied to the linearly-polarized light, and thereby calculating a value of the current to be measured.

6. A fault zone detection apparatus comprising the optical fiber electric current sensor according to claim 1, the apparatus using the optical fiber electric current sensor to detect a fault zone in an electric transmission cable that includes an imaginary cable and an underground cable.

7. A fault zone detection apparatus comprising the optical fiber electric current sensor according to claim 2, the apparatus using the optical fiber electric current sensor to detect a fault zone in an electric transmission cable that includes an imaginary cable and an underground cable.

8. A fault zone detection apparatus comprising the optical fiber electric current sensor according to claim 3, the apparatus using the optical fiber electric current sensor to detect a fault zone in an electric transmission cable that includes an imaginary cable and an underground cable.

9. A fault zone detection apparatus comprising the optical fiber electric current sensor according to claim 4, the apparatus using the optical fiber electric current sensor to detect a fault zone in an electric transmission cable that includes an imaginary cable and an underground cable.
